(19) United States
(12) Patent Application Publication
(10) Pub. No.: US 2014/0246781 A1
(43) Pub. Date: Sep. 4, 2014

(54) SEMICONDUCTOR DEVICE, METHOD OF FORMING A PACKAGED CHIP DEVICE AND CHIP PACKAGE

(71) Applicant: KABUSHIKI KAISHA TOSHIBA, Tokyo (JP)

(72) Inventor: Eiichi HOSOMI, Kanagawa (JP)

(73) Assignee: KABUSHIKI KAISHA TOSHIBA, Tokyo (JP)

(21) Appl. No.: 13/784,636

(22) Filed: Mar. 4, 2013

(51) Int. Cl. H01L 25/065

(52) U.S. Cl. CPC H01L 25/0657
USPC 257/774; 438/107

(57) ABSTRACT

According to one embodiment, the semiconductor device is of the multi-chip type. The semiconductor device has a embedded-chip-package-in-substrate, a wiring layer, and plural second chips. The embedded-chip-package-in-substrate has the first chip accommodated in it. The wiring layer is formed on the top surface of the embedded-chip-package-in-substrate. Plural second chips are stacked on the wiring layer.

### FIELD

Embodiments described herein relate to a semiconductor device, method of forming a packaged chip device and a chip package.

### BACKGROUND

In recent years, in the NAND flash memory and other memory devices, plural memory chips are stacked one over the other and connected vertically, and then accommodated in a package. Usually, a controller chip for controlling the operation of the memory chips is accommodated in the stack of chips. In this case, because the controller chip is typically smaller than the conventional memory chips, the controller chip is stacked on top of the memory chips.

In the memory device, the plural memory chips are interconnected with each other by connecting the bump electrodes of one chip to TSV's (Through-Silicon Via) of a second chip. Also, the power supply for the memory chips is provided from an underlying packaging substrate through connected bump electrodes.

On the other hand, the controller chip located over the stack of memory chips is connected to the packaging substrate by wires. In this case, the element forming surface of the controller chip faces downward. Consequently, the wires are connected to the back surface of the controller chip. In order to accommodate signal transmission by the wires, TSV's are also formed in the controller chip.

For the conventional chip stack structure, there are the following problems.

One problem is that because it is necessary to form TSV's through the controller chip, the manufacturing cost of the controller chip rises.

Another problem is, as the controller chip is stacked on the top of the memory devices, the wires for connecting the controller chip to the underlying packaging substrate become longer. Consequently, assembly failures like wire skew are prone to occur. This is undesirable.

When power is supplied from the packaging substrate to the memory chips, on the packaging substrate, it is necessary to form the pads for connection with the bump electrodes at the same pitch as that of the TSV's in the memory chips. The pitch of the TSV's is usually a fine pitch of about 40 to 50 μm. Consequently, the pads for connection of the bump electrodes on the packaging substrate side should also be closely spaced. As a result, the manufacturing cost of the packaging substrate rises, which is undesirable.

### DESCRIPTION OF THE DRAWINGS

FIG. 1 is a schematic cross-sectional view illustrating an example of the configuration of the semiconductor device according to a first embodiment.

FIG. 2 is a partial cross-sectional view illustrating an example of the structure of the vias for connection between the first chip and the second chip of the semiconductor device in the first embodiment.

FIG. 3 is a schematic cross-sectional view illustrating an example of the configuration of the semiconductor device in a second embodiment.

FIG. 4 is a schematic cross-sectional view illustrating an example of the configuration of the semiconductor device in a third embodiment.

FIG. 5 is a schematic cross-sectional view illustrating an example of the configuration of the semiconductor device according to a fourth embodiment.

FIG. 6 is a schematic cross-sectional view illustrating an example of the configuration of the semiconductor device according to a fifth embodiment.

FIG. 7 is a schematic cross-sectional view illustrating an example of the configuration of the semiconductor device according to a sixth embodiment.

### DETAILED DESCRIPTION

In general, according to one embodiment, a semiconductor device is of the multi-chip type, has a embedded-chip-package-in-substrate, a wiring layer, and plural second chips. The embedded-chip-package-in-substrate has the first chip accommodated therein. The wiring layer is formed on the top surface of the embedded-chip-package-in-substrate. Plural second chips are stacked on the wiring layer.

In the following, the embodiments of the present disclosure will be explained with reference to the drawings. The same keys as those in the above represent the same or similar parts.

### First Embodiment

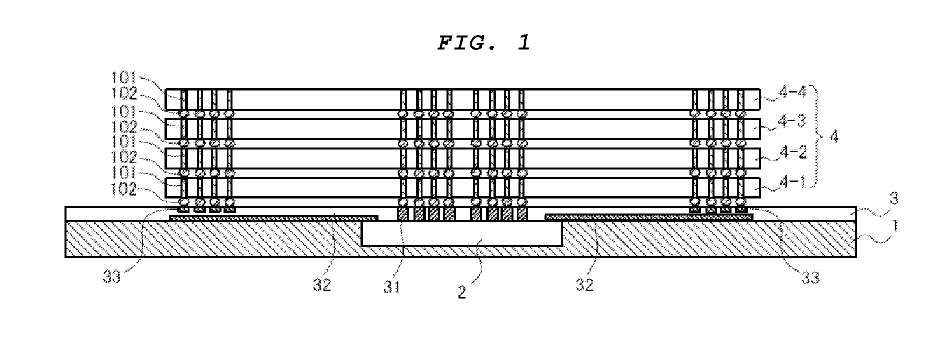

FIG. 1 is a schematic cross-sectional view illustrating an example of the configuration of the semiconductor device in the first embodiment.

The semiconductor device in this embodiment has a embedded-chip-package-in-substrate 1, a first chip 2 accommodated in a recess in the embedded-chip-package-in-substrate 1, a wiring layer 3 formed on the upper surf ace of the embedded-chip-package-in-substrate 1, and plural second chips 4 interconnect one over the other, the last of which (chip 4-1) is connected to the wiring layer 3.

In the example shown here, four second chips 4 (4-1, 4-2, 4-3, 4-4) are stacked. Here, the chip 4-1 is the bottom layer chip, and the chip 4-4 is the top layer chip. However, the number of the stacked chips is not limited to 4.

On the second chips 4, at least one TSV 101 is formed through the top surface and the bottom surface of the chip, or at least from the bottom surface to an active area in chip 4. The chips 4-1, 4-2, 4-3, 4-4 are interconnected with each other by the bumps 102 arranged at the position of the TSV's 101.

The second chips 4 may be memory chips. When the second chips 4 are memory chips, the first chip 2 should be a controller chip that controls the operation of the memory chips.

The controller chip usually is smaller than the memory chips. Here, the first chip 2 is accommodated in the embedded-chip-package-in-substrate 1.

The embedded-chip-package-in-substrate 1 may be a fan-out type wafer level package. The fan-out wafer level package allows formation of fine wiring processing of the wiring layer 3.

In a fan-out wafer level package, the chip is positioned on, and in electrical contact, with pads, contacts, etc and is positioned directly under the chip on an underlying substrate. The substrate is larger in area then the chip, so that the substrate projects outwardly from the edges of the chip. On the underside of the substrate are arranged contacts which correspond to the pads, etc, which contact the chip, and the pads, etc on the one side of the substrate are connected thereto through the body of the substrate. However, the area over which the contacts are positioned on the second side of the substrate is larger than the chips and it extends in the region underlying the area where the substrate extends outwardly from the chip, or fans out.

In the wiring layer 3, vias 31 are formed to connect the first chip 2 and the bottom layer chip 4-1 among the stacked second chips 4.

Also, in the wiring layer 3, a wiring 33 is formed to connect the first chip 2, and a wiring 32 is formed to connected to the bottom chip 4-1.

With the fan-out wafer level package, it is possible to carry out fine wiring processing of the wiring layer 3. Consequently, it is easy to form the wiring 33 matched with the fine configuration pitch of the TSV's 101 of the second chips 4.

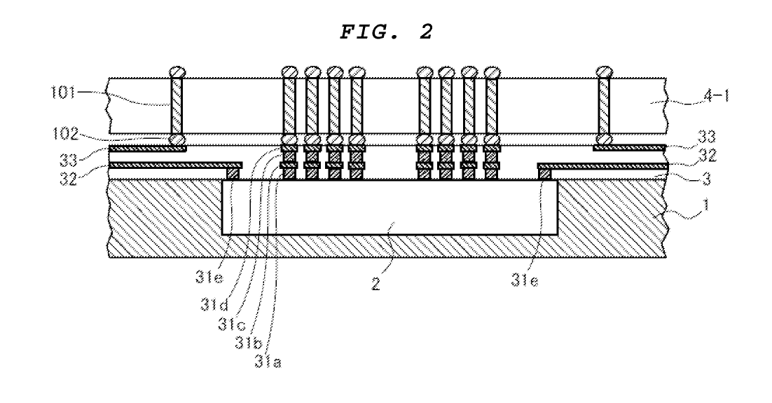

FIG. 2 shows an example of the detailed structure of the vias 31 that connect the first chip 2 and the chip 4-1. In the following, an example in which the vias 31 extending from controller chip 2 to the lowermost stacked chip 4-1 are formed in 2-stage structure in wiring layer 3 will be presented.

In this case, the first-stage via 31a connected to the first chip 2, the wiring layer metal 31b connected to the via 31a, the second-stage via 31c connected to the wiring layer 31b, and the wiring layer metal 31d connected to the via 31c are formed.

The wiring layer metal 31d is connected to the bumps 102 arranged on the bottom surface of the chip 4-1.

In addition, in the wiring layer 3, a via 31e that interconnects the first chip 2 and the wiring 32 is also formed.

In this way, according to the present embodiment, for example, the controller chip may be arranged beneath, and connected to the stacked memory chips.

### Second Embodiment

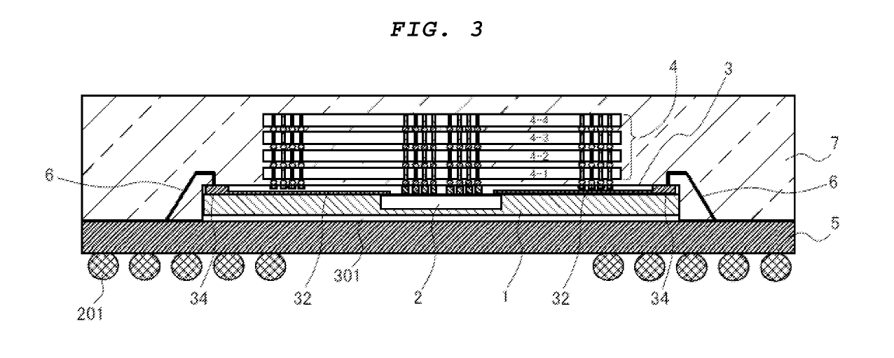

FIG. 3 is a schematic cross-sectional view illustrating an example of the configuration of the semiconductor device in the second embodiment. The same numerals as those used in the above in the first embodiment are adopted where the referenced structures are the same, and they thus will not be explained in detail again.

The semiconductor device of this embodiment has a packaging substrate 5.

According to the present embodiment, the semiconductor device in the first embodiment is arranged on the packaging substrate 5. The semiconductor device in the first embodiment is bonded on the packaging substrate 5 by an adhesive 301.

According to the present embodiment, pads 34 are formed on the top surface of the wiring layer 3. The pads 34 are connected to the first chip 2 via the wiring 32.

Wires 6 are connected between the packaging substrates 5 and the pads 34 by bonding opposed ends of the wires to the pads 34 and the packaging substrate 5. The first chip 2 is thus connected to the packaging substrate 5 via the wiring 32 and the wires 6.

To provide external connection to the resulting packaged devices, conductive balls 201 are position on the bottom surface of the packaging substrate 5.

According to the present embodiment, the semiconductor device has the top surface of the packaging substrate 5 sealed by resin 7. As a result, the entirety of the semiconductor device and the wires 6 of the first embodiment are protected from the external environment.

According to the present embodiment, by connecting the wires 6 to the pads 34 on the top surface of the wiring layer 3, the first chip 2 can be connected to the packaging substrate 5, and as a result, the wire connecting the first chip 2 to the packaging substrate 5 can be shortened.

Also, for example, when the first chip 2 is a controller chip, there is no need to form one or more TSV's in the controller chip. Consequently, it is possible to suppress rise in the manufacturing cost of the controller chip. In addition, there is no requirement of closer spacing of the connecting pads of the packaging substrate, so that it is possible to suppress the manufacturing cost of the packaging substrate.

### Third Embodiment

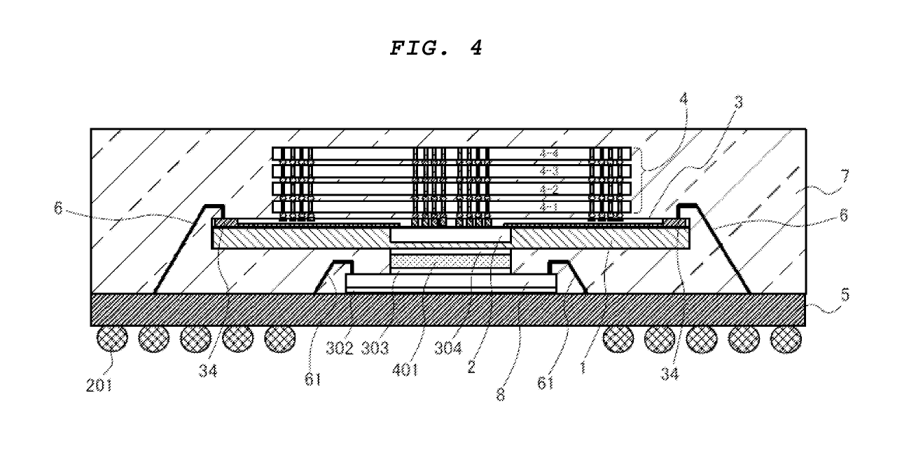

FIG. 4 is a schematic cross-sectional view illustrating an example of the configuration of the semiconductor device in the third embodiment. Where the same numerals as those used in the second embodiment are adopted, they will not be again explained in detail.

For the semiconductor device in the present embodiment, a third chip 8 is also stacked between the packaging substrate 5 and the embedded-chip-package-in-substrate 1. The third chip 8 may be made of a logic LSI that uses stacked memories.

The third chip 8 is bonded onto the packaging substrate 5 by an adhesive 302. The third chip 8 is connected to the packaging substrate 5 by the wires 61. In order to establish the wire connecting space, a spacer 401 is bonded by adhesive 303 on the third chip 8.

The embedded-chip-package-in-substrate 1 is bonded by adhesive 304 on the spacer 401.

Alternatively, the third chip 8 may also be stacked on the top chip 4-4 of the second chips 4. In this case, the third chip 8 can be connected to the pads 34 arranged on the top surface of the wiring layer 3 by wires. As a result, it is possible to shorten the wires to lengths shorter than when required for direct wire connection to the packaging substrate 5.

Also, when the size of the third chip 8 is small, it is also possible arrange the third chip 8 on the packaging substrate 5 by the side of the embedded-chip-package-in-substrate 1. Also, the third chip 8 may be sealed in the embedded-chip-package-in-substrate 1.

In this way, according to the present embodiment, in addition to the effect of the second embodiment, the following effect can be realized: for example, in addition to the stacked memory chips and the controller chip, the logic LSI using the stacked memories or the like may be accommodated in a single package.

### Fourth Embodiment

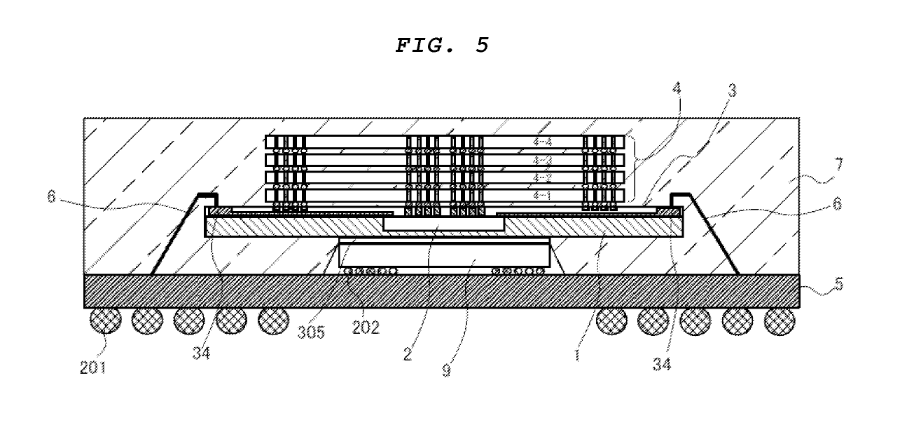

FIG. 5 is a schematic cross-sectional view illustrating an example of the configuration of the semiconductor device in the fourth embodiment of the present disclosure. The same numerals as those in the above in the third embodiment are adopted here, and the structures thereof will not be explained in detail again.

In the semiconductor device according to the present embodiment, just as in the third embodiment, a third chip 9 is also stacked between the packaging substrate 5 and the embedded-chip-package-in-substrate 1.

The third chip 9 is connected to the packaging substrate 5 by flip chip bonding.

The third chip 9 is bonded by adhesive 305 with the embedded-chip-package-in-substrate 1. Bump electrodes 202 are connected to the bottom surface of the third chip 9. By the bump electrodes 202, the third chip 9 is connected to the packaging substrate 5.

According to the present embodiment, in addition to the effects of the third embodiment, the following effect can also be realized: the power supply for the third chip 9 is fed via the bump electrodes 202. Consequently, the power supplied to the third chip 9 may be higher. As a result, it is possible to use a high-performance device as the third chip 9.

### Fifth Embodiment

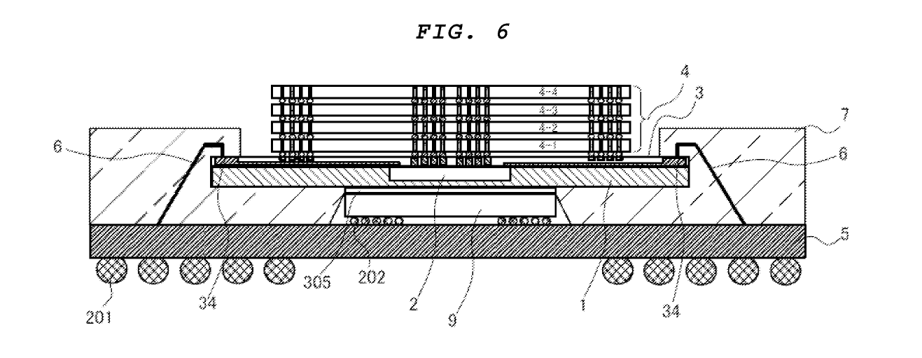

FIG. 6 is a schematic cross-sectional view illustrating an example of the configuration of the semiconductor device according to the fifth embodiment of the present disclosure. The same numbers as those in the above in the fourth embodiment are adopted here, and the structures that they represent will not be explained in detail again.

In the second through fourth embodiments, the entirety of the package is sealed off by the resin 7 for the semiconductor device. On the other hand, according to the present embodiment, only the portion for connecting the embedded-chip-package-in-substrate 1 and the packaging substrate 5 is sealed off by the resin 7. As a result, at least the wires 6 are covered by the resin 7, so that the wires 6 are protected from the ambient environment.

On the other hand, the second chips 4 are not covered with the resin 7, so that they are exposed to the ambient environment.

FIG. 6 is a diagram illustrating an example of the resin sealing for the semiconductor device with otherwise the same configuration as that of the fourth embodiment. However, the present disclosure is not limited to the example. The same resin sealing also can be carried out for the semiconductor devices with the configurations of other embodiments.

Consequently, according to the present embodiment, the second chips 4 are exposed to the ambient environment, so that it is possible to improve the heat dissipation performance of the second chips.

### Sixth Embodiment

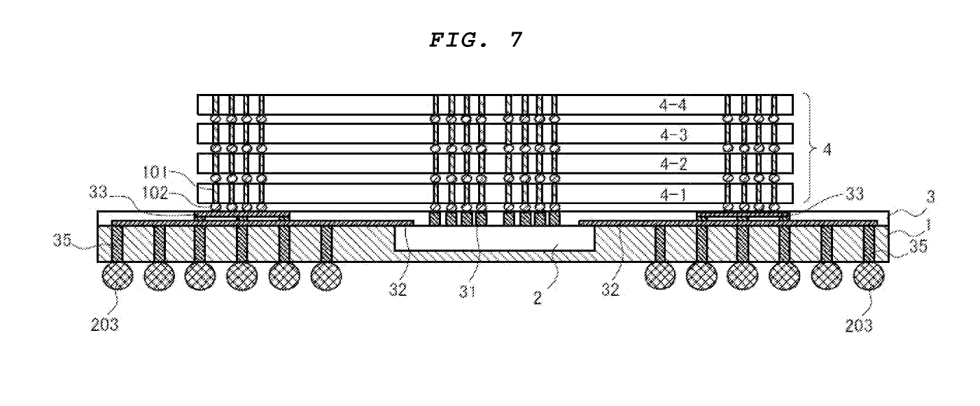

FIG. 7 is a schematic cross-sectional view illustrating an example of the configuration of the semiconductor device according to the sixth embodiment. Where the same numbers as those in the above in the first embodiment are adopted, the structures they reference will not be explained in detail again.

In the second embodiment through the fifth embodiment, the semiconductor device of the first embodiment adopts the balls 201 connected to the packaging substrate 5 as the external terminals.

On the other hand, according to the present embodiment, the external terminals are arranged directly on the semiconductor device of the first embodiment.

For the semiconductor device in this embodiment, on the bottom surface of the embedded-chip-package-in-substrate 1 of the semiconductor device of the first embodiment, the balls 203 are connected as the external terminals. At the sites where the balls 203 are arranged, the vias 35 are formed through between the top surface and the bottom surface of the embedded-chip-package-in-substrate 1.

Through the vias 35, the wiring 32 connected to the first chip 2 and the wiring 33 connected to the chip 4-1 are connected to the balls 203.

According to this embodiment, connection to the external terminals can be carried out even without using the packaging substrate. As a result, it is possible to decrease the external dimensions of the semiconductor device than those when a packaging substrate is in use.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A multi-chip-type semiconductor device, comprising:
an embedded-chip-package-in-substrate having a first chip accommodated therein, a wiring layer formed on the top surface of the embedded-chip-package-in-substrate, and
a plurality of second chips connected one on the next, and the plurality of connected chips connected to the wiring layer through one of the connected chips.

2. The semiconductor device according to claim 1, further comprising:
a packaging substrate, wherein
the embedded-chip-package-in-substrate is arranged on the packaging substrate.

3. The semiconductor device according to claim 2, wherein the wiring layer includes pads and the first chip is connected to at least one pad formed on the wiring layer, and at least a second pad and the packaging substrate are connected with each other by wires.

4. The semiconductor device according to claim 3, wherein
the second chips are memory chips, and
the first chip is a controller chip that controls the operation of the memory chips.

5. The semiconductor device according to claim 4, wherein
the chip of the controller chip is recessed in the embedded-chip-package-in-substrate and is smaller than the size of the memory chips, and
the embedded-chip-package-in-substrate is a fan-out wafer level package.

6. The semiconductor device according to claim 3, wherein the wires are encapsulated.

7. The semiconductor device according to claim 3, wherein:
at least one of a spaces or a third chip are interposed between the packaging substrate and the embedded-chip-package-in-substrate.

8. The semiconductor device according to claim 7, wherein
the third chip and the packaging substrate are connected to each other by wires; and
at least a top surface of the packaging substrate is sealed off by a resin so that at least the wires are not exposed.

9. The semiconductor device according to claim 7, wherein
the third chip and the packaging substrate are connected to each other by flip chip bonding.

10. The semiconductor device according to claim 3, further comprising:
a third chip that is stacked on the top-layer chip of the second chips.

11. A method of forming a packaged chip device, comprising;
providing a substrate having a recess therein;
positioning a chip, having electrical contacts on a face thereof, in the recess with the contacts exposed;
positioning at least one second chip, having surface, in an overlying position of the first chip such that surfaces of the second chip extend to a position where they do not overlie the first chip, the second chip having electrical contacts on the portions of the surface overlying the first chip and on portions thereof not overlying the first chip; and
providing wiring between the first chip and the portions of the surface of the second chip overlying the first chip and the portions of the second chip not over lying the first chip.

12. The method of forming a package chip device of claim 11, further including:
providing the substrate to have a substrate surface larger than the second chip surface;
extending a package wiring over the substrate surface outwardly of the position of the second then cover; and
connecting a wire from the wiring layer on a packaging substrate.

13. The method of forming a packaged chip device of claim 12, further including connecting the substrate to the packaging substrate, and encapsulating the wire.

14. The method of forming a packaged chip device of claim 13, further including providing an additional chip in a position between the substrate and the packaging substrate, or overlying a second chip.

15. A chip package, comprising:
a first substrate having a recess therein;
a first chip, having contact pads thereon, received in the recess;
a second chip overlying the recess and at least a portion of the first substrate, and being physically spaced from the first chip, the second chip having at least one electrical contact formed on the surface thereof, facing and spaced from the first chip; and
an interconnect structure extending between a pad on the first chip and the contact on the second chip for electrical connection there between.

16. The chip package of claim 15, wherein the portion of the second chip overlying the substrate includes at least one electrical contact thereon, and, an electrical interconnect extends from a second pad on the first chip to the contact on the portion of the second chip overlying the substrate.

17. The chip package of claim 15, further including a wiring layer extending from a contact position with a pad on the first chip to a position on the substrate not overlaid with the second chip.

18. The chip package of claim 17, wherein the second chip includes a second surface, and a via extending from the surface facing the first chip to the second surface, and;
a third chip is electrically connected to the second surface of the first chip.

19. The chip package of claim 15, wherein the first chip is a controller chip and the second chip is a memory chip.

20. The chip package of claim 15, further including a chip other than a controller chip and a memory chip.
